(19) United States
(12) Patent Application Publication
(10) Pub. No.: US 2003/0212935 A1
(43) Pub. Date: Nov. 13, 2003

(54) Circuit and method for accelerating the test time of a serial access memory device

(76) Inventors: Rodney W. Roark, Colorado Springs, CO (US); Mary E. Hackbarth, Colorado Springs, CO (US); John C. Walbert, Colorado Springs, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/142,258

(22) Filed: May 9, 2002

(51) Int. Cl. G11C 29/00

(52) U.S. Cl. 714/719

(57) ABSTRACT

A serial memory device includes a test mode for accelerating the writing of externally-supplied data into the memory array by ganging column address so that a single clock writes a single row. Data is retrieved from the memory either by singularly addressed locations or by mirrored address locations across a memory boundary with retrieved data being individually compared via logic asserted during testing operations. Depending on the requested test mode, the compare results can return an order for continuance of array testing or insertion of complemented data into the currently-compared memory location and continuance of array testing. A GO/No Go indication is provided via output circuitry controlled by the test mode.

### BACKGROUND OF THE INVENTION

This invention pertains to serial memory devices, and, more particularly, to improving test cycle time for a serial access, integrated circuit ferroelectric memory.

Current testing methods for serial memories require single-cell reading and writing for functionality or retention testing. Due to serial protocol overhead, testing becomes more cost prohibitive as densities increase.

Referring now to FIG. 1, a block diagram of a prior art serial memory device 10 is shown having a typical data access. Serial memory 10 includes a left memory block 12, which is a portion of the total memory array. The output of left memory block 12 is shifted into a left shift register 16. Similarly, serial memory 10 includes a right memory block 14, which is the remaining portion of the total memory array. The output of right memory block 14 is shifted into a right shift register 18. The outputs of shift registers 16 and 18 are multiplexed through multiplexer 20 to provide one byte of data per testing cycle.

As shown in FIG. 1, previous serial designs required that testing of the array data be performed one byte at a time. Each byte had to be individually written and then individually read for accuracy. Test times greatly increase as the density of memories increase due to the protocol overhead required for serial device access.

Referring now to FIG. 2, a typical write sequence is shown for a serial memory. The chip select (“CS”), serial clock (“SCK”), serial input (“SI”), and serial output (“SO”) waveforms are shown. After the CS waveform goes low, various instruction sequences are supplied to the memory device before any data is actually written into the memory. In FIG. 2, the Write Opcode (one byte wide), the Upper Address Byte (one byte wide), and the Lower Address Byte (one byte wide), must be processed by the serial memory 10 before any data is written into the memory array. Depending upon the exact design implemented, additional eight-bit sequences may be required. For example, an eight-bit sequence (not shown) may be required to set an internal latch, or to provide other memory housekeeping functions.

Referring now to FIG. 3, a typical read sequence is shown for a serial memory. The chip select (“CS”), serial clock (“SCK”), serial input (“SI”), and serial output (“SO”) waveforms are again shown. After the CS waveform goes low, various instruction sequences must be processed by the memory before any data is actually read from the memory. In FIG. 3, the Read Opcode (one byte wide), the Upper Address Byte (one byte wide), and the Lower Address Byte (one byte wide), must be processed by the serial memory 10 before any data is read from the memory array. Depending upon the exact design implemented, additional eight-bit sequences may be required.

Once the data bytes have been introduced for writing or reading, each byte of written or read data requires eight clock (SCK) cycles. For a 64 K-bit array to be completely written, 65,568 clock cycles are required. The reading of the same array requires 65,560 clock cycles. The frequency of the serial clock determines the actual time of testing. However, complete test cycle time is greatly extended by the increasing memory density of serial parts, the “instruction overhead” associated with reading and writing data, and the fact that generally more than one sequence of complete array writing and reading is required for proper testing.

What is desired, therefore, is a circuit and method associated with a serial memory device that can greatly reduce total testing time, while maintaining testing integrity.

### SUMMARY OF THE INVENTION

According to the present invention, upon entry into a test mode, the improved serial memory device accelerates writing of externally-supplied data into the memory array by ganging column address whereby a single clock writes a single row. Data is retrieved from the memory either by singularly addressed locations or by mirrored address locations across a memory boundary with retrieved data being individually compared via logic asserted during testing operations. Depending on the requested test mode, the compare results can return an order for continuance of array testing or insertion of complemented data into the currently-compared memory location and continuance of array testing. A GO/No Go indication is provided via output circuitry controlled by the test mode.

It is an advantage of the present invention that it facilitates improved efficiency of testing for pre-released product by availing quicker memory loading and comparison of memory data for detection of errant memory cells.

The foregoing and other objects, features and advantages of the invention will become more readily apparent from the following detailed description of a preferred embodiment of the invention, which proceeds with reference to the accompanying drawings.

### BRIEF DESCRIPTION OF THE DRAWINGS

FIG. 1 is a block diagram of a prior art serial memory device;

FIG. 2 is a timing diagram of a typical write sequence for a prior art serial memory device;

FIG. 3 is a timing diagram of a typical read sequence for a prior art serial memory device;

FIG. 4 is a block diagram of a serial memory device according to the present invention including additional circuitry for improving total test cycle time;

FIG. 5 is a timing diagram of a testing sequence for a serial memory device according to the present invention;

FIG. 6 is a block diagram of the additional circuitry and associated control signals for improving test; and

FIG. 7 is a flow chart showing the testing method steps of the present invention.

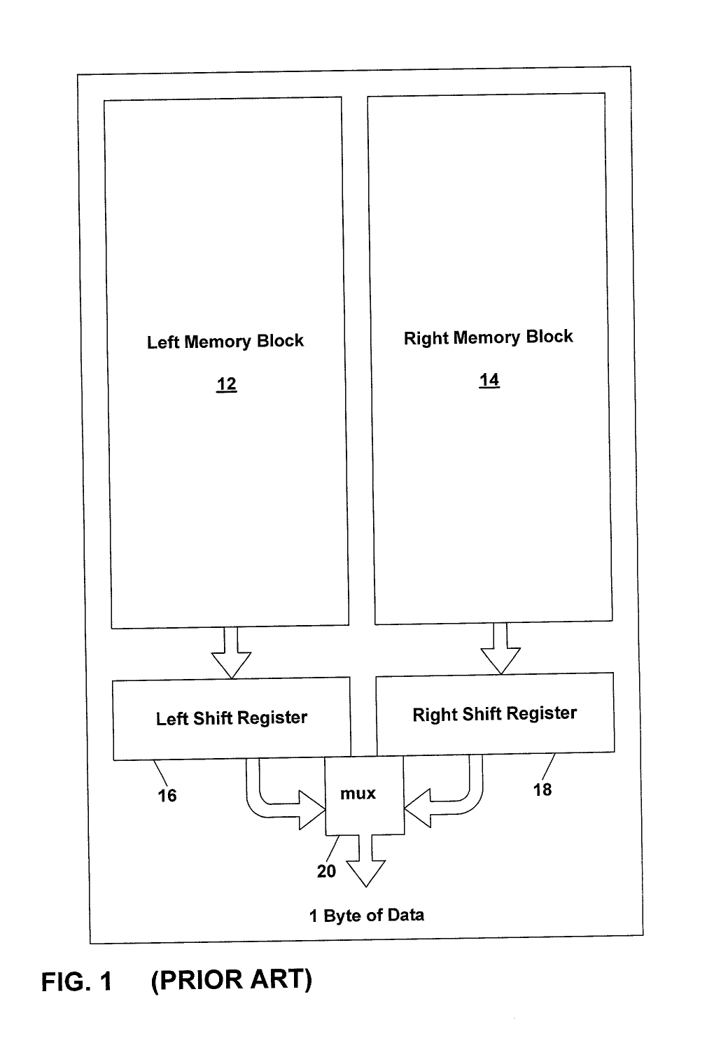

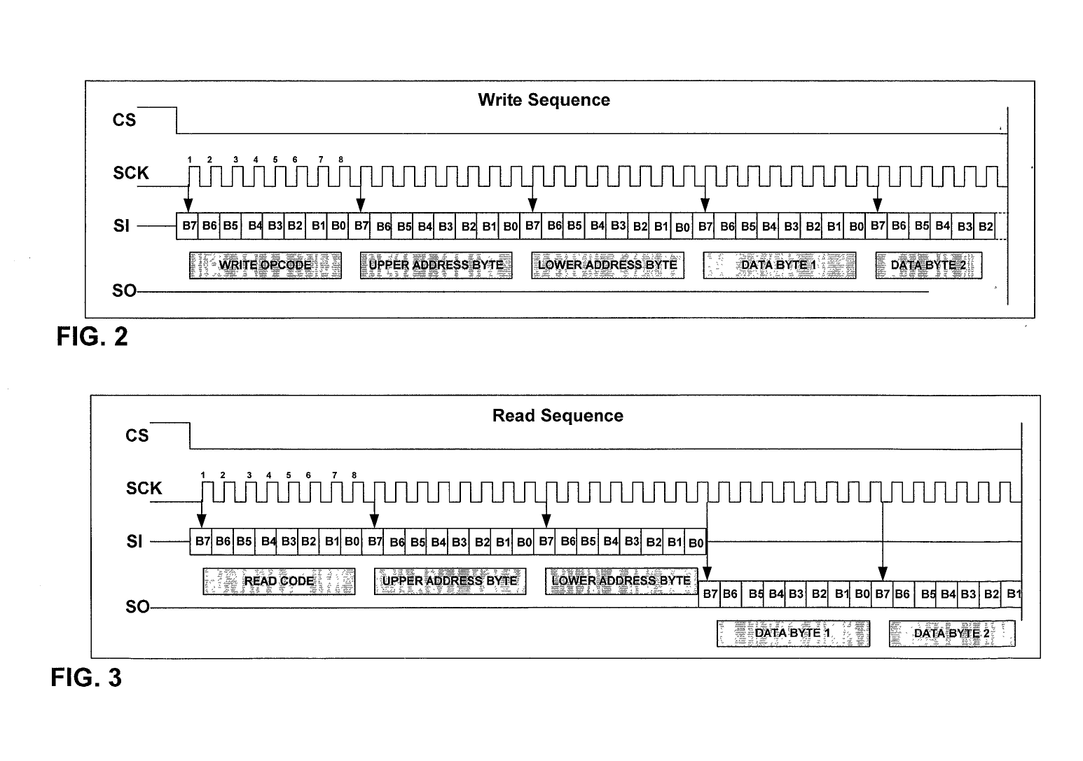

### DETAILED DESCRIPTION

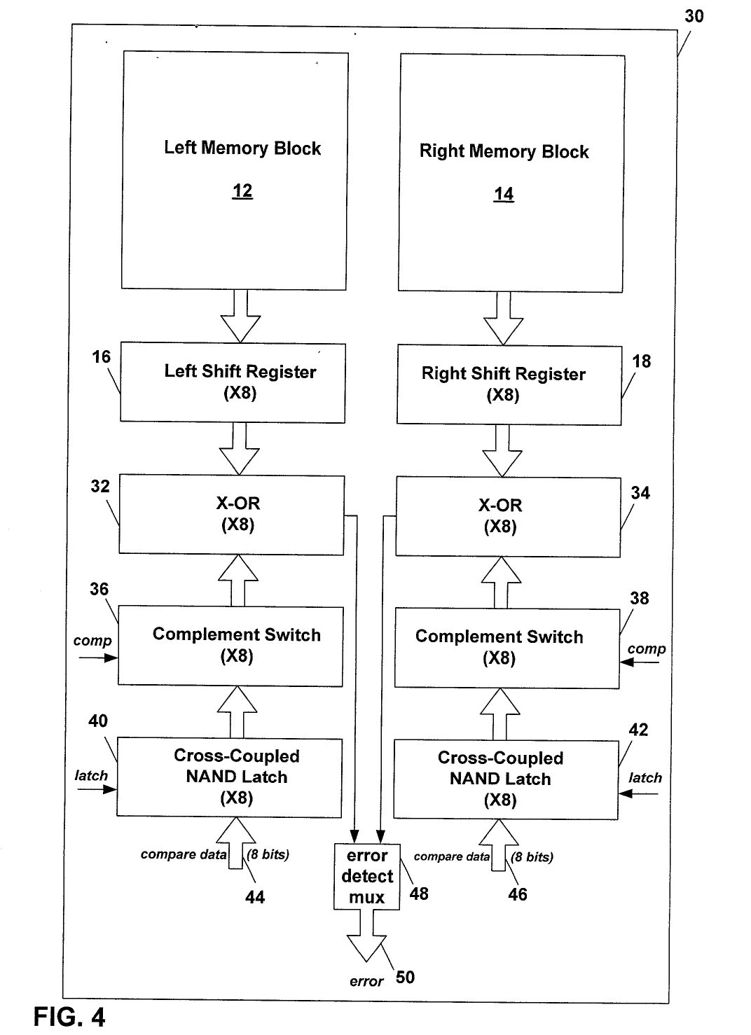

Referring now to FIG. 4 compare circuitry has been added to a standard serial memory device 30 in order to compress testing cycle time. Notice that latches 40 and 42, X-OR logic blocks 32 and 34, and complement switches 36 and 38 have been added. The left and right memory blocks 12 and 14, and left and right shift registers 16 and 18 remain as in the standard serial memory device. An error detecting multiplexer receives output signals from X-OR blocks 32 and 34. When a device is intended to be tested, a special test mode sequence is presented to the part for separate, test logic to become active. The test logic is integral to the state machine, not shown in FIG. 4, which controls all functions of the device. Thus, the test logic controls multiple internal signals for address ganging, cell access, and I/O control, as well as the COMP and LATCH signals, as is described in further detail below. Part of the test mode sequence is a byte of comparison data, which is used as the comparison base for data retrieved from the memory array.

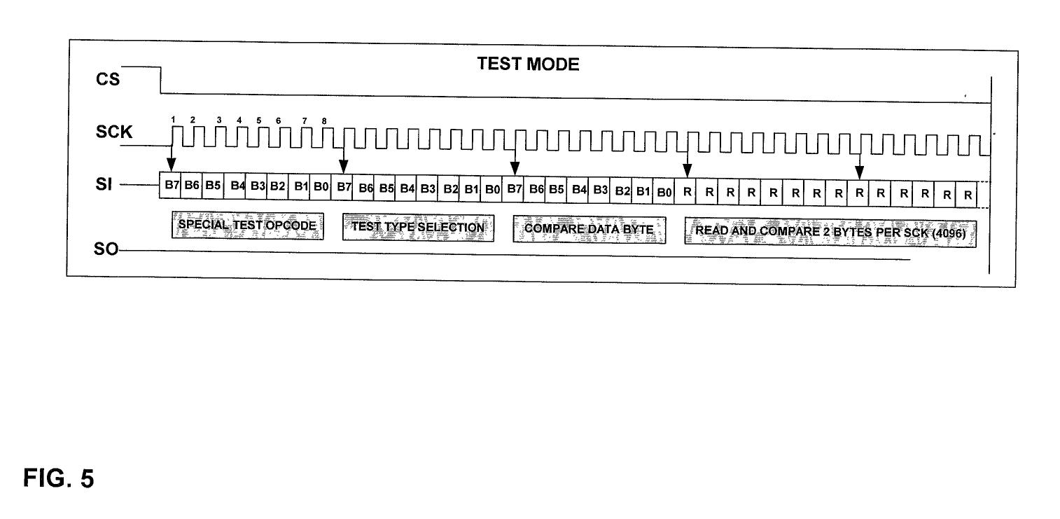

FIG. 5 is a timing diagram that illustrates the improved test mode sequence of the present invention. FIG. 5 illustrates a serial device entering the test mode whereby once the test entry requirements are satisfied and the user-supplied compare byte is loaded, each clock cycle will interrogate and compare two bytes of data. As was previously stated, 65,560 clock cycles are required to test every byte of a 64-Kilobte memory. Utilizing the new test method of the present invention, only 4,120 clock cycles are required for a thorough, bit-by-bit check of the memory array.

In FIG. 5, “Special Test Opcode” refers to a special means of accessing and directing the serial device privy to test personnel and not available to the normal user of the device. “Test Type Selection” refers to the exact test mode to be implemented, which is ordered through the “Special Test Opcode” such as “test read”, “test write”, complement, and other test mode conditions. “Compare Data Byte” refers to the byte of data supplied by test personnel, which is the comparison base for array data. “Read and Compare 2 Bytes Per SCK” refers to the input clock stimulus whereby the serial device obtains its synchronous execution.

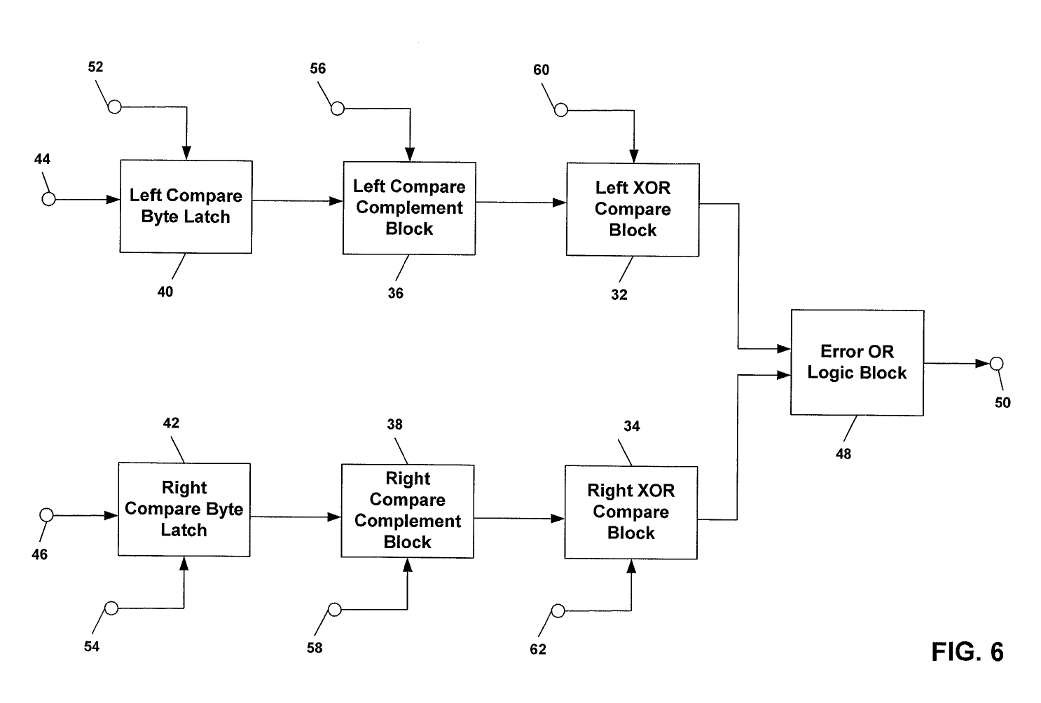

A full schematic of the additional compare circuit is shown in FIG. 6. A left compare byte latch 40 receives the left shifted data 44. A right compare byte latch 42 receives the right shifted data 46. Latches 40 and 42 are ideally cross-coupled NAND latches as is known in the art, and can be fabricated in CMOS logic on the same substrate as the memory array and shift registers. A left compare complement block 36 receives the output signal from latch 40. A right compare complement block 38 receives the output signal from latch 42. Complement blocks 36 and 38 are CMOS inverters that can complement the input data upon command as is discussed below. A left XOR compare block 32 receives the output signal from complement block 36. A right XOR compare block 38 receives the output signal from complement block 38. The XOR blocks can be fabricated in CMOS logic as is known in the art, and integrated onto the same substrate as all of the other circuitry shown in FIG. 6. Finally an error OR logic block 48 receives the two output signals from XOR blocks 32 and 34 to generate an output signal as is discussed in further detail below.

The following signals are used to control the compare circuitry shown in FIG. 6: the COMP signal is used as a signal to instigate the complement of compare byte when comparing alternating-row data patterns from the memory array and are input on terminals 36 and 38; the LATCH signal is issued once the compare byte of data has been loaded and is input on terminals 52 and 54; the ERROR signal is a global signal used for indication that a byte read from the memory array doesn't match supplied compare byte and is output on terminal 50; and the COMPARE DATA is a byte of user-supplied data used as comparison base for memory array data and is input on terminals 44 and 46. Shifted data from the memory array is input into the circuitry of FIG. 6 at terminals 60 and 62.

Normally, data stored in any memory device is more or less randomly distributed. However, in order to thoroughly test individual memory cells, various ordered patterns of testing data are sometimes implemented. For example, the part under test may be written in a pattern such that each row has the complement data from the previous row. When comparing alternating data, the COMP signal, feeding the “complement” blocks 36 and 38, is activated to make sure the user-supplied compare byte becomes a complement of itself for an accurate comparison.

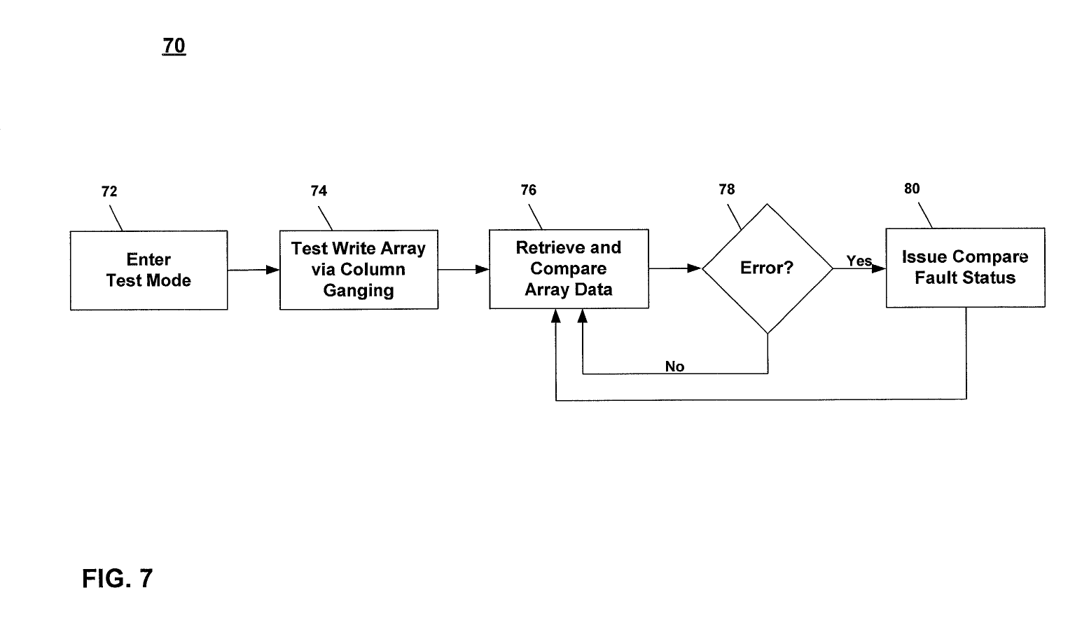

Referring now to FIG. 7, a flow chart 70 sets forth a test flow according to the method of the present invention. In step 72, the memory device under test is placed into the test mode. In step 74, the data is prepared for testing. In step 76, the data is retrieved and compared to known data. In step 78, the results of the comparison between the array data and external data are monitored. If there are no errors, additional data is compared and the process is continued until all of the data is tested, or until an error is found. If an error is found at step 80, a fault status command is issued. The fault status command can be used to completely halt the testing process of the device under test at that point, or to continue testing under the same or different test conditions as desired.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

We claim:

1. A serial memory comprising:
a left memory array;
a right memory array;
a left shift register coupled to the left memory array;
a right shift register coupled to the right memory array;
a left latch for receiving externally applied compare data;
a right latch for receiving externally applied compare data;
a left complement switch coupled to the left latch;
a right complement switch coupled to the right latch;
a left comparator for comparing data from the left shift register to data from the left complement switch;
a right comparator for comparing data from the right shift register to data from the right complement switch; and
an error detecting multiplexer coupled to the left and right comparators for providing an output error signal.

2. The serial memory as in claim 1 in which the left and right memory arrays each comprise a ferroelectric memory array.

3. The serial memory as in claim 1 in which the left and right shift registers each comprise an eight-bit shift register.

4. The serial memory as in claim 1 in which the left and right latches each comprise a cross-coupled NAND latch.

5. The serial memory as in claim 1 in which the left and right latches each further comprise an input for receiving latch control signal.

6. The serial memory as in claim 1 in which the left and right complement switches each further comprise an input for receiving a complement control signal.

7. The serial memory as in claim 1 in which the left and right comparators each comprise an XOR logic block.

8. The serial memory as in claim 1 in which the serial memory comprises an integrated circuit ferroelectric serial memory.

9. A testing circuit for a serial memory comprising:
a left latch for receiving externally applied compare data;
a right latch for receiving externally applied compare data;
a left complement switch coupled to the left latch;
a right complement switch coupled to the right latch;
a left comparator for comparing shifted data from a first portion of the serial memory to data from the left complement switch;
a right comparator for comparing shifted data from a second portion of the serial memory to data from the right complement switch; and
an error detecting multiplexer coupled to the left and right comparators for providing an output error signal.

10. The serial memory as in claim 9 in which the serial memory comprises a ferroelectric serial memory.

11. The serial memory as in claim 9 in which the left and right latches each comprise a cross-coupled NAND latch.

12. The serial memory as in claim 9 in which the left and right latches each further comprise an input for receiving latch control signal.

13. The serial memory as in claim 9 in which the left and right complement switches each further comprise an input for receiving a complement control signal.

14. The serial memory as in claim 9 in which the left and right comparators each comprise an XOR logic block.

15. A testing circuit for a serial memory comprising:
a latch for receiving externally applied data; and
a comparator for comparing shifted data from the serial memory to data supplied by the latch, and for supplying an error signal if the serial memory data is different from the externally applied data.

16. The serial memory as in claim 15 in which the serial memory comprises a ferroelectric serial memory.

17. The serial memory as in claim 15 in which the latches comprises a cross-coupled NAND latch.

18. The serial memory as in claim 15 in which the latches further comprises an input for receiving a latch control signal.

19. The serial memory as in claim 15 in which the comparator comprises an XOR logic block.

20. A method for testing a serial memory comprising:
latching externally applied data;
shifting data out of the serial memory;
comparing the shifted data from the serial memory to the externally applied latched data; and
providing an error signal if the serial memory data is different from the externally applied data.

21. The method of claim 20 further comprising discontinuing testing of the serial memory in response to the error signal.
